(19) United States
(12) Patent Application Publication
(10) Pub. No.: US 2015/0003016 A1
(43) Pub. Date: Jan. 1, 2015

(54) SEMICONDUCTOR DEVICE AND SEMICONDUCTOR SYSTEM

(71) Applicants: Noboru Miyamoto, Tokyo (JP); Takaaki Shirasawa, Tokyo (JP)

(72) Inventors: Noboru Miyamoto, Tokyo (JP); Takaaki Shirasawa, Tokyo (JP)

(73) Assignee: MITSUBISHI ELECTRIC CORPORATION, Tokyo (JP)

(21) Appl. No.: 14/361,757

(22) PCT Filed: Mar. 19, 2012
(86) PCT No.: PCT/JP2012/057035

§ 371 Date: May 30, 2014

(51) Int. Cl. H01L 23/473; H01L 23/16

(52) U.S. Cl. CPC H01L 23/473; H01L 23/16
USPC 361/701

(57) ABSTRACT

It is an object of the present invention to provide a semiconductor device which is easily replaceable and a semiconductor system using the semiconductor device. The semiconductor device of the present invention includes a semiconductor chip, a cooler that cools the semiconductor chip, a housing that houses the semiconductor chip and the cooler, a transfer resin that seals the semiconductor chip and the cooler inside the housing, electrodes connected to the semiconductor chip, and a joining pipe attached to the cooler, the joining pipe letting in and out a flow of a refrigerant from and to the cooler. The electrodes and the joining pipe are formed to protrude from the same surface of the housing in substantially the same direction.

### TECHNICAL FIELD

The present invention relates to a method for facilitating replacement of a semiconductor device.

### BACKGROUND ART

Conventionally, packaged power modules need gel sealing in power semiconductor elements, which leads to a problem that the number of assembling processes increases and component cost increases.

Thus, transfer molding type power modules in which power semiconductor elements are molded by transfer molding have been developed. The transfer molding type power module is combined with a shield plate, a control substrate, and a cooling fin to complete a semiconductor device. Patent Document 1 discloses the prior arts related to the present invention.

### PRIOR ART DOCUMENT

### Patent Document

Patent Document 1: Japanese Patent Application Laid-Open No. 2001-250890

### SUMMARY OF INVENTION

### Problem to be Solved by the Invention

In recent times, electric vehicles and plug-in hybrid vehicles having a charging function have been developed. A semiconductor device installed on such vehicles is required to charge during stopping in addition to driving and charging during moving, which have taken place in the hybrid vehicles, so that a current-carrying load increases and long life is required.

On the other hand, semiconductor elements generate heat when being energized, and stress caused by heat fluctuations is applied to a joint of the semiconductor elements. Thus, to achieve long life, expensive materials need to be used for a joint and a heat dissipation material of the semiconductor elements. Although long life is achieved, initial performances cannot be satisfied at the end of life and fuel economy or the like may deteriorate. Consequently, a semiconductor device, which is easily replaceable when performances deteriorate, is required.

The present invention has been made in view of the above mentioned problems, and an object thereof is to provide a semiconductor device which is easily replaceable and a semiconductor system using the semiconductor device.

### Means to Solve the Problem

A semiconductor device of the present invention is a semiconductor device including a semiconductor chip, a cooler that cools the semiconductor chip, a housing that houses the semiconductor chip and the cooler, a sealing resin that seals the semiconductor chip and the cooler inside the housing, electrodes connected to the semiconductor chip, and a joining pipe attached to the cooler, the joining pipe letting in and out a flow of a refrigerant from and to the cooler, and the electrodes and the joining pipe are formed to protrude from the same surface of the housing in substantially the same direction.

### Effects of the Invention

A semiconductor device of the present invention includes a semiconductor chip, a cooler that cools the semiconductor chip, a housing that houses the semiconductor chip and the cooler, a sealing resin that seals the semiconductor chip and the cooler inside the housing, electrodes connected to the semiconductor chip, and a joining pipe attached to the cooler, the joining pipe letting in and out a flow of a refrigerant from and to the cooler. The electrodes and the joining pipe are formed to protrude from the same surface of the housing in substantially the same direction, so that if a semiconductor container having a connection structure of an electrode or a joining pipe corresponding to the same surface of the semiconductor device is prepared, the semiconductor device is inserted, and at the same time a high-voltage system and a cooling system can be connected. Thus, the semiconductor device can be easily replaced.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a cross sectional view of a semiconductor container and a semiconductor device according to a first embodiment;

FIG. 2 is a cross sectional view showing a state in which the semiconductor device according to the first embodiment is housed in the semiconductor container;

FIG. 3 is a side view and a top view showing a semiconductor device according to a second embodiment;

FIG. 4 is a flow chart showing an operation of a semiconductor device according to a third embodiment; and

FIG. 5 is a diagram for describing the operation of the semiconductor device according to the third embodiment.

### DESCRIPTION OF EMBODIMENTS

### A. First Embodiment

### A-1. Configuration and Operation

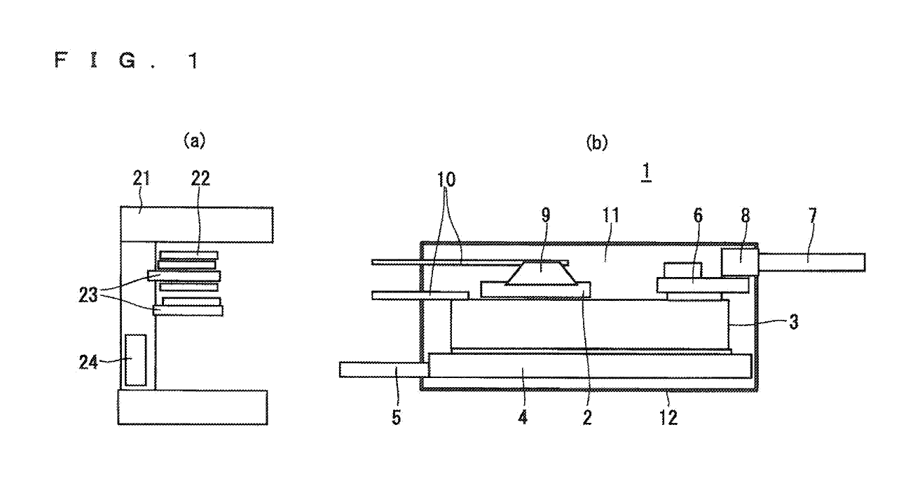

FIG. 1 is a cross sectional view of a semiconductor container and a semiconductor device according to a first embodiment. Portion (a) of FIG. 1 shows a semiconductor container 21, and portion (b) of FIG. 1 shows a semiconductor device 1.

The semiconductor device 1 includes a semiconductor chip 2, a heat spreader 3 attached to a back of the semiconductor chip 2, and an insulating cooler 4 attached to a back of the heat spreader 3. A semiconductor driving circuit 6 for driving the semiconductor chip 2 is attached onto the heat spreader 3 in addition to the semiconductor chip 2. The structural components of the semiconductor device 1 as described above are housed in a housing 12, and the inside of the housing 12 is sealed with a transfer resin 11.

A communication cable 7 connected to the semiconductor driving circuit 6 through a communication connector 8 protrudes from one surface of the housing 12. Communications between the semiconductor driving circuit 6 and a higher-level system which is not shown take place through the communication cable 7.

An electrode 10 is connected to a surface of the semiconductor chip 2 by a solder 9, and another electrode 10 is also connected to the heat spreader 3. These electrodes 10 protrude to the outside of the housing 12 from a surface of the housing 12 facing a surface from which the communication cable 7 protrudes. In addition, a joining pipe 5 of the cooler 4 also protrudes from the same surface of the housing 12 in the same direction as the electrodes 10. The joining pipe 5 is formed of a resin material or coated with a resin to secure a creepage distance from the electrodes 10.

The semiconductor container 21 has a U-shaped cross sectional shape as shown in portion (b) of FIG. 1. A dimension of a U-shaped recessed portion corresponds to a dimension of the housing 12 of the semiconductor device 1, and the housing 12 can be inserted and housed in the portion. The semiconductor container 21 has a cooling channel 24 inside, and moreover, two pairs of connection electrodes 22 are integrally located inside the semiconductor container 21. The two pairs of connection electrodes 22 are provided with insulating layers 23 therebetween.

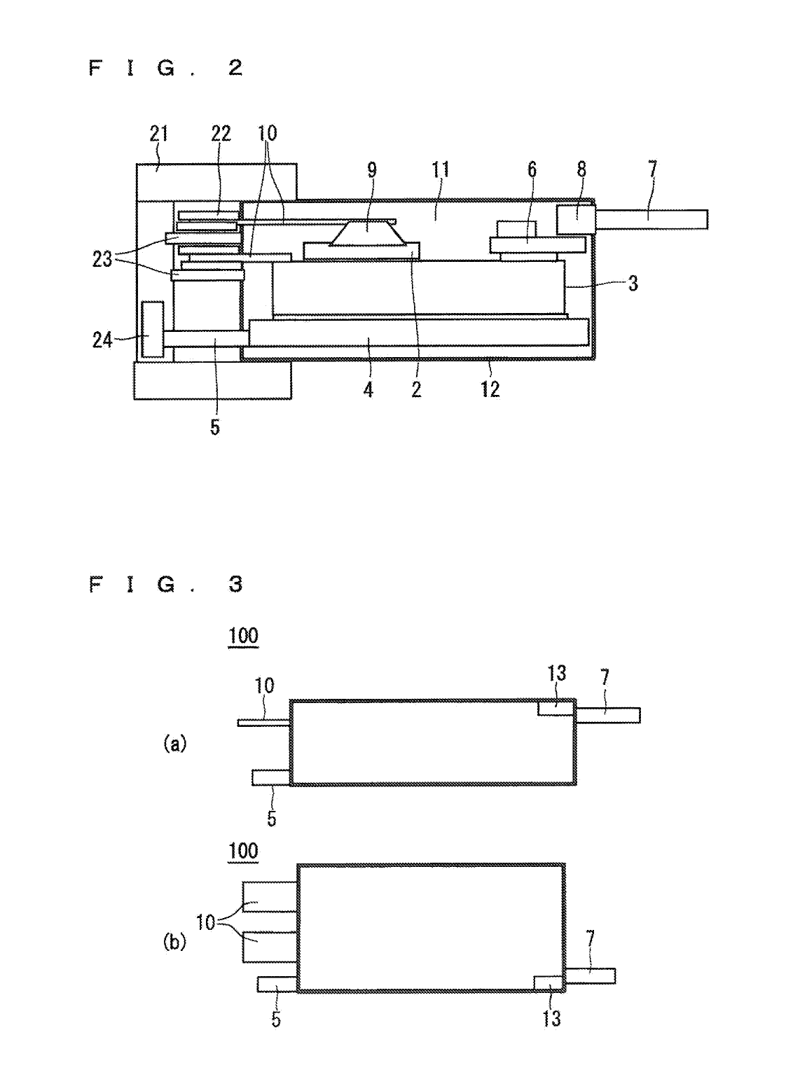

FIG. 2 is a cross sectional view showing a state in which the semiconductor device 1 is housed in the semiconductor container 21. The surface of the housing 12 from which the electrodes 10 and the joining pipe 5 protrude is inserted into the semiconductor container 21 to house the semiconductor device 1 in the semiconductor container 21. In this state, the electrodes 10 are connected to the connection electrodes 22, and the joining pipe 5 is connected to the cooling channel 24. The electrodes 10 and the joining pipe 5 are located to protrude from the same surface of the housing 12 in the same direction, so that the semiconductor device 1 is inserted into the semiconductor container 21 to connect a high-voltage system and a cooling system, thereby facilitating an assembly of the semiconductor device 1. Moreover, the semiconductor device 1 can be easily replaced in a case where its performances deteriorate.

Furthermore, FIGS. 1 and 2 show the example in which the heat spreader 3 and the cooler 4 are located on the back surface side of the semiconductor chip 2, but they may be located on both sides of the semiconductor chip 2. In this case, the electrodes 10 are located on a side of the semiconductor chip 2, and moreover, the heat spreader 3 and the cooler 4 are located on a surface of the semiconductor chip 2. Alternatively, the heat spreader 3 and the cooler 4 may also be located on the transfer resin 11 through an insulating plate. The configuration as described above can improve cooling capability of the semiconductor chip 2.

### A-2. Effects

The semiconductor device 1 according to the embodiment is a semiconductor device including a semiconductor chip 2, a cooler 4 that cools the semiconductor chip 2, a housing 12 that houses the semiconductor chip 2 and the cooler 4, a transfer resin 11 that seals the semiconductor chip 2 and the cooler 4 inside the housing 12, electrodes 10 connected to the semiconductor chip 2, and a joining pipe 5 attached to the cooler 4, the joining pipe letting in and out a flow of a refrigerant from and to the cooler 4, and the electrodes 10 and the joining pipe 5 are formed to protrude from the same surface of the housing 12 in substantially the same direction. With this configuration, the semiconductor device 1 is housed in the semiconductor container 21 along the direction in which the electrodes 10 and the joining pipe 5 protrude, and at the same time the high-voltage system and the cooling system are connected, thereby facilitating the assembly of the semiconductor device 1. The semiconductor device 1 can be easily removed in the reverse procedure to the assembly, thereby facilitating the replacement of the semiconductor device 1.

In the semiconductor device 1, the joining pipe 5 of the cooler 4 is formed of a resin or the surface of the joining pipe 5 is coated with a resin layer to secure the creepage distance from the connection electrodes 22, thereby improving insulating performance.

The semiconductor device 1 further includes the communication cable 7 for communication of a control signal between an external source and the semiconductor chip 2, and the communication cable 7 is formed to protrude from a surface facing the same surface of the housing 12, from which the electrodes 10 and the joining pipe 5 protrude.

The semiconductor device 1 is removable from the semiconductor container 21 formed of the connection electrodes 22 and the cooling channel 24 integrally formed with each other, and in a state of being mounted to the semiconductor container 21, the electrodes 10 and the joining pipe 5 are connected to the connection electrodes 22 and the cooling channel 24, respectively. Thus, the semiconductor device 1 can be easily removed from the semiconductor container 21, thereby facilitating the replacement.

The cooler 4 is located on both surface sides of the semiconductor chip 2 in the semiconductor device 1, thereby improving the cooling capability of the semiconductor chip 2.

### B. Second Embodiment

### B-1. Configuration and Operation

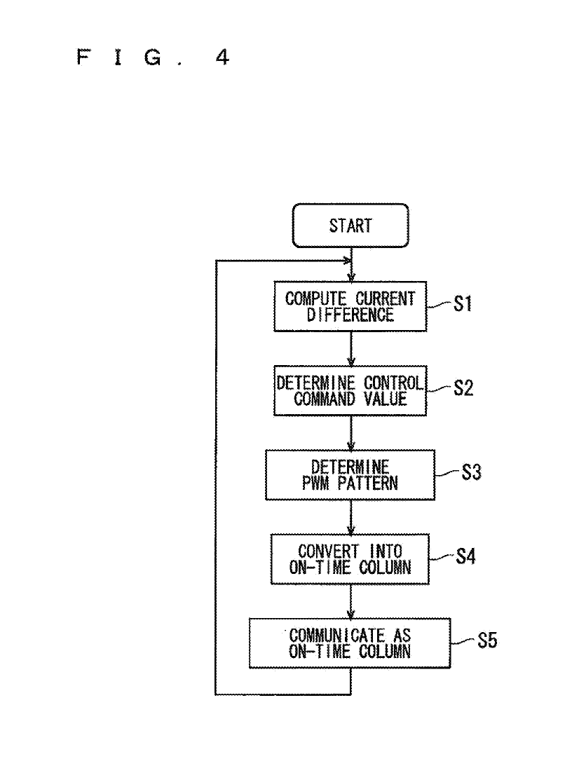

Portion (a) of FIG. 3 shows a side view of a semiconductor device 100 of a second embodiment, and portion (b) of FIG. 3 shows a top view thereof. The semiconductor device 100 is different from the semiconductor device 1 of the first embodiment in that the semiconductor device 100 includes an indicator 13.

The indicator 13 determines the degree of deterioration or failure of the semiconductor chip 2 with a determination portion, which is not shown, incorporated in the semiconductor device 100 from a temperature output, leakage current, or the like of the semiconductor chip 2 and emits light in a preset pattern according to the determination result. Thus, in a case where a plurality of semiconductor devices 100 are installed, a user is able to distinguish a semiconductor device, which is needed to be replaced, by checking the light emitting state of the indicator 13. The replacement itself can be easily performed similarly to the semiconductor device 1 of the first embodiment.

As shown in FIG. 3, the indicator 13 has light emitting surfaces in directions along each surface, so that the light emitting state can be visually identified from both of the upper surface side and the side surface side of the housing 12. This may be achieved by the one indicator 13 having the light emitting areas on the upper surface side and the side surface side of the housing 12, and this may also be achieved by providing another indicator 13 on the upper surface side and the side surface side of the housing 12.

In a case where light communication is used for communication of a control command and a sensor signal between the semiconductor device 100 and a higher-level device, a light emitting element for means of light communication may also function as a light emitting element of the indicator 13.

The indicator 13 may be given a function of holding electric power for a period of time by a capacitor or the like which is not shown. Consequently, although power is shut off, the indicator 13 emits light for a period of time, and thus even after the power is shut off, a user can grasp the semiconductor device 100 to be replaced.

### B-2. Effects

The semiconductor device 100 of the embodiment includes the indicator 13 that emits light in pattern corresponding to the degree of deterioration or failure of the semiconductor chip 2, and the indicator 13 has the light emitting surfaces along at least two or more surfaces of the housing 12. Thus, a user can recognize, from the light emitting pattern of the indicator 13, the semiconductor device 100 to be replaced.

The light emitting element for the light communication with the external device doubles as the indicator 13, whereby the configuration of the semiconductor device 100 can be simplified.

If the indicator 13 has a function of holding electric power to emit light for a period of time, the semiconductor device 100 to be replaced can be recognized after the power is shut off.

### C. Third Embodiment

### C-1. Configuration and Operation

A semiconductor system of the embodiment includes the plurality of semiconductor devices 1 as described in the first embodiment and drive control signal generation means that drives the semiconductor chip 2 of the semiconductor devices 1. The drive control signal generation means is connected to each of the semiconductor devices 1 by the communication cable 7, and the semiconductor driving circuit 6 receives a drive control signal from the drive control signal generation means to drive the semiconductor chip 2.

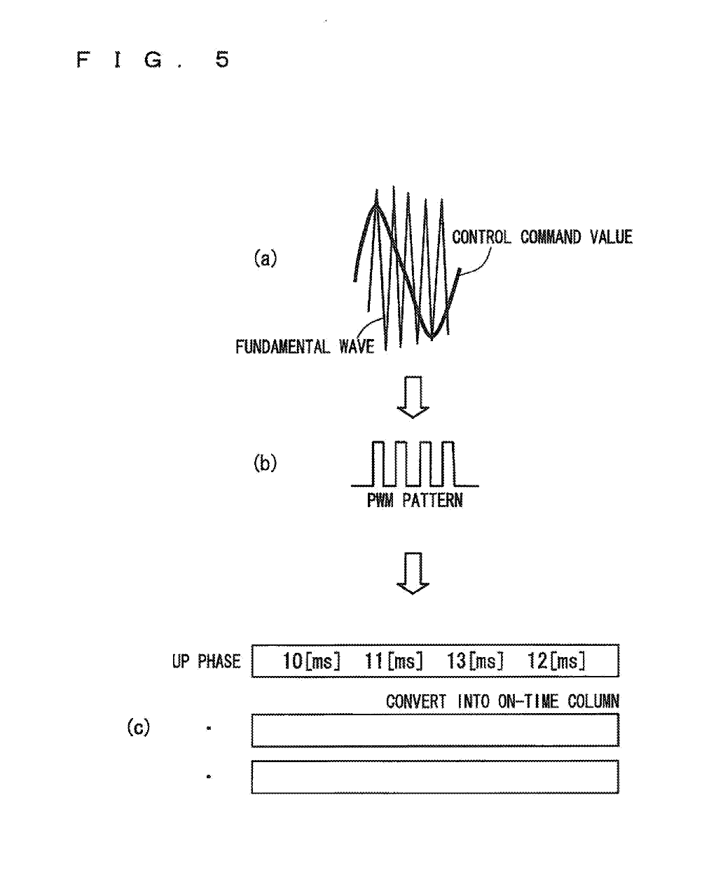

FIG. 4 is a flow chart showing an operation of the drive control signal generation means and showing an algorithm that modulates an AC waveform by PWM and outputs the AC waveform. First of all, this algorithm computes a difference between a target current and an actual current detected by a current sensor or the like (target current-actual current) (step S1). A feedback control algorithm such as Hoc control determines a control command value based on the deviation (step S2). Then, the control command value and a fundamental wave (triangular wave) are compared to each other (portion (a) of FIG. 5), and a PWM drive signal is generated (step S3, portion (b) of FIG. 5).

In general, to control the semiconductor devices 1, the PWM drive signal is directly inputted into the semiconductor devices 1 and the semiconductor devices 1 sequentially process the signal to drive the semiconductor chip 2. Thus, in a case of a common three-phase inverter for example, a total of six signal lines that sequentially perform a process are needed for two arms on top and bottom×three phases.

However, the actual control signal changes at every cycle of each feedback control process. Consequently, the drive control signal generation means repeatedly transmits a signal having the same pattern between the feedback control process at some point and the next feedback control process.

Thus, in the embodiment, the PWM signal of the phase whose control command value is determined in step S2 is converted into ON-time column (step S4, portion (c) of FIG. 5) with the addition of a recognition code corresponding to each semiconductor device to be bundled and sent as a set of data to the communication cable 7. A semiconductor device corresponding to each phase obtains a driving pattern of its own phase from the recognition code and generates its own drive signal based on the pattern.

For this configuration, a drive control signal can be transmitted to a plurality of semiconductor devices with one signal line, and the communication cable 7 can be formed of one communication line which allows for a two-way communication.

The input algorithm of the drive control signal for the semiconductor devices 1 of the first embodiment is described above, and it is also similar to the semiconductor device 100 of the second embodiment.

### C-2. Effects

A semiconductor system includes a plurality of the semiconductor devices 1 and 100 and drive control signal generation means that generates signals for controlling driving of the semiconductor chips 2 of the semiconductor devices 1 and 100 in a feedback process and outputs the signals to the semiconductor devices 1 and 100, and the drive control signal generation means bundles commands to the plurality of semiconductor devices 1 and 100 into a piece of data at time intervals shorter than cycles of the feedback process and transmits the piece of data, whereby one signal line can transmit the drive control signals to the plurality of semiconductor devices 1 and 100.

While the invention has been shown and described in detail, the foregoing description is in all aspects illustrative and not restrictive. The present invention is not restricted to that. It is therefore understood the numerous modifications and variations can be devised without departing from the scope of the invention.

### DESCRIPTION OF NUMERALS

1, 100 semiconductor device;

2 semiconductor chip;

3 heat spreader;

4 cooler;

5 joining pipe;

6 semiconductor driving circuit;

7 communication cable;

8 communication connector;

9 solder;

10 electrodes;

11 transfer resin;

12 housing;

13 indicator;

21 semiconductor container;

22 connection electrodes;

23 insulating layers;

24 cooling channel;

1. A semiconductor device, comprising:
a semiconductor chip;
a cooler that cools said semiconductor chip;
a housing that houses said semiconductor chip and said cooler;
a sealing resin that seals said semiconductor chip and said cooler inside said housing;
an electrode connected to said semiconductor chip; and
a joining pipe attached to said cooler, said joining pipe letting in and out a flow of a refrigerant from and to said cooler,
wherein said electrode and said joining pipe are formed to protrude from the same surface of said housing in substantially the same direction.

2. The semiconductor device according to claim 1, wherein said joining pipe of said cooler is formed of a resin or a surface thereof is coated with a resin layer.

3. The semiconductor device according to claim 1, further comprising a communication cable for communication of a control signal between an external source and said semiconductor chip,
wherein said communication cable is formed to protrude from a surface facing the same surface of said housing, from which said electrode and said joining pipe protrude.

4. The semiconductor device according to claim 1 which is configured to be removable from a semiconductor container formed of a connection electrode and a cooling channel integrally formed with each other,
wherein in a state of being mounted to said semiconductor container, said electrode and said joining pipe are connected to said connection electrode and said cooling channel, respectively.

5. The semiconductor device according to claim 1, wherein said cooler is provided on both surface sides of said semiconductor chip.

6. The semiconductor device according to claim 1, further comprising an indicator that emits light in a pattern corresponding to a degree of deterioration or failure of said semiconductor chip,
wherein said indicator has light emitting surfaces along at least two or more surfaces of said housing.

7. The semiconductor device according to claim 6, wherein said indicator also functions as a light emitting element for light communication with an external device.

8. The semiconductor device according to claim 6, wherein said indicator has a function of holding electric power to emit light for a period of time.

9. A semiconductor system, comprising:
a plurality of semiconductor devices according to claim 1; and
drive control signal generation means that generates signals for controlling driving of the semiconductor chips of said semiconductor devices in a feedback process and outputs said signals to said semiconductor devices,
wherein said drive control signal generation means bundles commands to said plurality of semiconductor devices into a piece of data at time intervals shorter than cycles of said feedback process and transmits said piece of data.
